(19) United States
(12) Patent Application Publication
(10) Pub. No.: US 2026/0101772 A1
(43) Pub. Date: Apr. 9, 2026

(54) SEMICONDUCTOR DEVICE

(71) Applicants: Kabushiki Kaisha Toshiba, Kanagawa (JP); Toshiba Electronic Devices & Storage Corporation, Kanagawa (JP)

(72) Inventor: Daisuke Inoue, Himeji Hyogo (JP)

(21) Appl. No.: 19/313,242

(22) Filed: Aug. 28, 2025

(30) Foreign Application Priority Data
Sep. 20, 2024 (JP) 2024-163642

(51) Int. Cl. H01L 23/00; H01L 23/495

(52) U.S. Cl. CPC H10W 70/417; H10W 70/481; H10W 72/07652; H10W 72/627; H10W 72/637; H10W 72/646; H10W 72/652; H10W 72/681; H10W 72/886; H10W 90/736; H10W 90/767

(57) ABSTRACT

According to one embodiment, a semiconductor device includes the following structure. The semiconductor chip is provided between first and second conductors. A joint component is provided between the chip and the second conductor. The thin film is provided on the second conductor and contains a material different from a material of the joint component. The second conductor includes first, second and third plates. The first plate extends in a first direction along a first surface of the chip and is connected to the chip via the joint component. The second plate extends from the first plate obliquely with respect to the first direction. The third plate extends from the second plate in the first direction. The thin film is arranged on a surface of the second plate continuous from a surface on which the joint component is provided.

### CROSS-REFERENCE TO RELATED APPLICATIONS

This application is based upon and claims the benefit of priority from Japanese Patent Application No. 2024-163642, filed Sep. 20, 2024, the entire contents of which are incorporated herein by reference.

### FIELD

Embodiments described herein relate generally to a semiconductor device.

### BACKGROUND

A semiconductor device including a semiconductor package on which a semiconductor chip is mounted is known.

### BRIEF DESCRIPTION OF DRAWINGS

FIG. 1 is a perspective view illustrating an outer shape of a semiconductor device according to a first embodiment.

FIG. 2 is a plan view illustrating the outer shape of the semiconductor device according to the first embodiment.

FIG. 3 is a cross-sectional view illustrating the configuration of the semiconductor device according to the first embodiment.

FIG. 4 is a cross-sectional view illustrating a connection structure between a semiconductor chip and a conductor according to the first embodiment.

FIG. 5 is a cross-sectional view illustrating a connection structure between a semiconductor chip and a conductor according to a comparative example.

FIG. 6 is a cross-sectional view illustrating a connection structure between a semiconductor chip and a conductor according to a second embodiment.

FIG. 7 is a cross-sectional view illustrating a connection structure between a semiconductor chip and a conductor according to a third embodiment.

### DETAILED DESCRIPTION

In general, according to one embodiment, a semiconductor device includes a first conductor, a second conductor, a semiconductor chip, a first joint component and a thin film. The semiconductor chip is provided between the first conductor and the second conductor. The first joint component is provided between the semiconductor chip and the second conductor. The thin film is provided on the second conductor. The film contains a material different from a material of the first joint component. The second conductor includes a first plate, a second plate, and a third plate. The first plate extends in a first direction along a first surface of the semiconductor chip and is connected to the semiconductor chip via the first joint component. The second plate extends from the first plate obliquely with respect to the first direction. The third plate extends from the second plate in the first direction. The thin film is arranged on a surface of the second plate continuous from a surface on which the first joint component is provided.

Hereinafter, embodiments will be described with reference to the drawings. In the following description, components having the same function and configuration are denoted by the same reference numeral. The following embodiments exemplify an apparatus and a method for embodying the technical idea of the embodiments, and do not specify the material, shape, structure, arrangement and the like of the components as follows.

### 1. First Embodiment

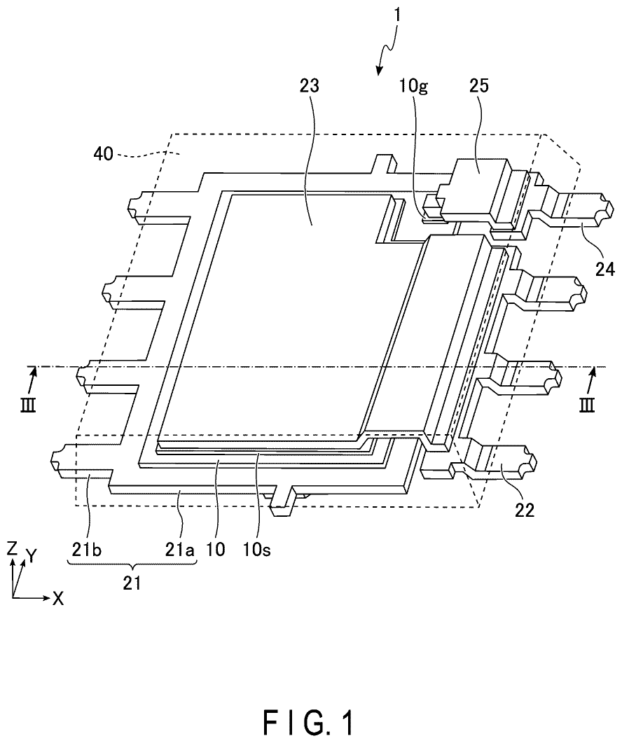

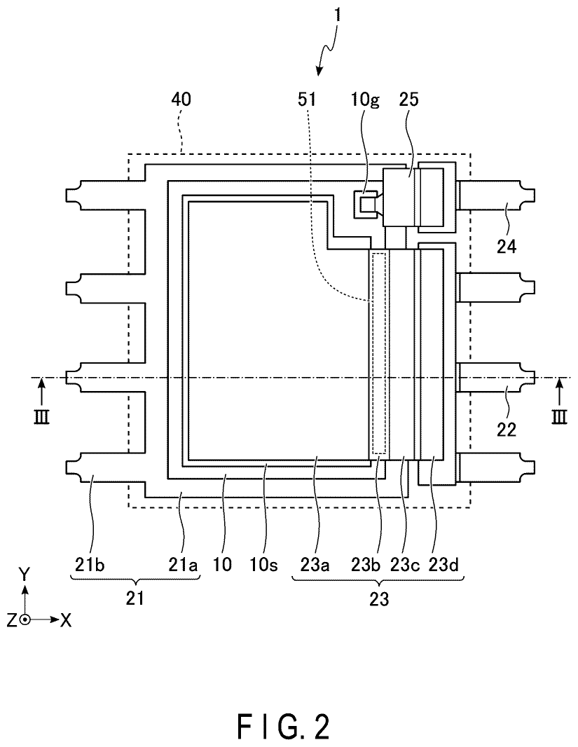

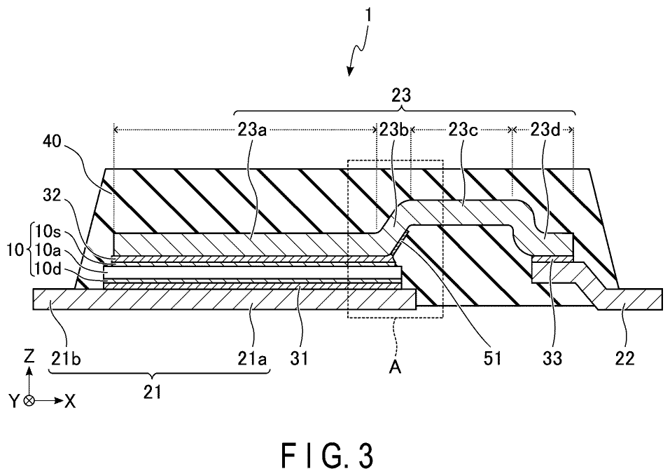

A semiconductor device according to a first embodiment is described. FIG. 1 is a perspective view illustrating an outer shape of the semiconductor device according to the first embodiment. FIG. 2 is a plan view illustrating the outer shape of the semiconductor device according to the first embodiment. FIG. 3 is a cross-sectional view of the semiconductor device taken along line III-III in FIGS. 1 and 2. FIGS. 1 and 2 are diagrams as seen through a resin member covering the semiconductor device. In the following description, in FIGS. 1 to 3, a direction of an arrow in an X direction is simply referred to as an X direction, and a direction opposite to the arrow is referred to as a −X direction. As for a Y direction and a Z direction, similarly, directions of arrows in the Y direction and the Z direction are simply referred to as the Y direction and the Z direction, respectively, and directions opposite to the arrows are referred to as a −Y direction and a −Z direction. The Z direction is referred to as upward, and the −Z direction is referred to as downward in some cases.

As illustrated in FIG. 3, a semiconductor device 1 includes a semiconductor chip 10, conductors 21 to 25, joint components (or joint materials, connection members, connection materials, connectors) 31 to 33, and a resin member 40. The semiconductor chip 10 is provided between the conductor 21 and the conductor 23. Furthermore, the conductor 23 is provided on the conductor 22.

The semiconductor chip 10 includes, for example, a metal oxide semiconductor field effect transistor (MOSFET) or an insulated gate bipolar transistor (IGBT). Here, a case where the semiconductor chip 10 is the MOSFET is described.

The semiconductor chip 10 includes, for example, a source electrode 10s, a drain electrode 10d, a gate electrode 10g, and a semiconductor layer 10a. The semiconductor layer 10a is provided between the source electrode 10s and the drain electrode 10d. Note that, the source electrode 10s and the drain electrode 10d may be interchanged as necessary.

The semiconductor chip 10 includes a first surface and a second surface. The first surface is a surface provided on the Z direction side, and the second surface is a surface provided on the −Z direction side. The source electrode 10s is provided on the first surface of the semiconductor chip 10. The drain electrode 10d is provided on the second surface of the semiconductor chip 10.

The conductor 21 is a part of a lead frame on which the semiconductor chip 10 is placed. The conductor 21 includes a base 21a and a plurality of protrusions 21b. The conductor 21 mainly contains, for example, a conductive material such as copper.

The base 21a is a region on which the semiconductor chip 10 is placed. The semiconductor chip 10 is provided on the base 21a of the conductor 21. The conductor 21 is arranged so as to face the drain electrode 10d of the semiconductor chip 10, and is electrically connected to the drain electrode 10d.

The plurality of protrusions 21b is regions extending from the base 21a in the −X direction. The plurality of protrusions 21b functions as lead terminals (for example, drain terminals) connectable to the outside.

The joint component 31 is provided between the semiconductor chip 10 and the conductor 21. The joint component 31 fixes the semiconductor chip 10 to the base 21a of the conductor 21. Therefore, the drain electrode 10d of the semiconductor chip 10 is electrically connected to the conductor 21 via the joint component 31. The joint component 31 mainly contains a conductive material such as solder or silver.

A plurality of conductors 22 is provided so as to be separated from the conductor 21 in the X direction and is arrayed in the Y direction. The conductor 22 is a part of the lead frame. The conductor 22 functions as a lead terminal (for example, a source terminal) connectable to the outside. The conductor 22 mainly contains, for example, a conductive material such as copper.

The conductor 23 is provided on the source electrode 10s of the semiconductor chip 10 and the conductor 22. The conductor 23 is arranged so as to face the source electrode 10s of the semiconductor chip 10 and the conductor 22, and is electrically connected to the source electrode 10s and the conductor 22. The conductor 23 mainly contains, for example, a conductive material such as copper.

The conductor 23 includes a portion (or a first plate) 23a, a portion (or a second plate) 23b, a portion (or a third plate) 23c, and a portion (or a fourth plate) 23d. The portion 23a is a region facing the semiconductor chip 10 and electrically connected to the semiconductor chip 10. The portion 23a is a region extending along the first surface of the semiconductor chip 10, that is, a region extending linearly in the X direction. The portion 23d is a region facing the conductor 22 and electrically connected to the conductor 22. The portions 23b and 23c are regions between the portion 23a and the portion 23d, and are regions that do not face neither the semiconductor chip 10 nor the conductor 22. The portion 23b is a region continuous from the portion 23a and extending linearly from the portion 23a in an oblique direction with respect to the X direction and the Z direction. The portion 23c is a region continuous from the portion 23b and extending linearly from the portion 23b in the X direction.

Furthermore, the portion 23d is a region continuous from the portion 23c, bent from the portion 23c in the −Z direction, and further extending along an upper surface of the conductor 22, that is, extending linearly in the X direction. With such a structure, by increasing a distance between the portion 23c of the conductor 23 and the conductor 21, an insulation property between the conductor 23 and the conductor 21 can be enhanced.

A thin film 51 is provided on a lower surface of the portion 23b of the conductor 23. The thin film 51 will be described later in detail.

A joint component 32 is provided between the portion 23a of the conductor 23 and the semiconductor chip 10. The joint component 32 fixes the conductor 23 to the semiconductor chip 10. Therefore, the source electrode 10s of the semiconductor chip 10 is electrically connected to the conductor 23 via the joint component 32. The joint component 32 mainly contains a conductive material such as solder or silver.

The joint component 33 is provided between the portion 23d of the conductor 23 and the conductor 22. The joint component 33 fixes the conductor 23 to the conductor 22. Therefore, the conductor 22 is electrically connected to the conductor 23 via the joint component 33. The joint component 33 mainly contains a conductive material such as solder or silver.

As illustrated in FIGS. 1 and 2, the conductor 24 is provided so as to be separated from the conductor 22 in the Y direction. The conductor 24 is a part of the lead frame. The conductor 24 functions as a lead terminal (for example, a gate terminal) connectable to the outside. The conductor 24 mainly contains, for example, a conductive material such as copper.

The conductor 25 is provided on the gate electrode 10g of the semiconductor chip 10 and the conductor 24. The conductor 25 is arranged so as to face the gate electrode 10g of the semiconductor chip 10 and the conductor 24, and is electrically connected to the gate electrode 10g and the conductor 24. The conductor 25 mainly contains, for example, a conductive material such as copper.

Furthermore, the resin member 40 covers the semiconductor chip 10, a part of the conductor 21, a part of the conductor 22, the conductor 23, a part of the conductor 24, and the conductor 25. The resin member 40 resin-seals the semiconductor chip 10 and the conductors 21 to 25.

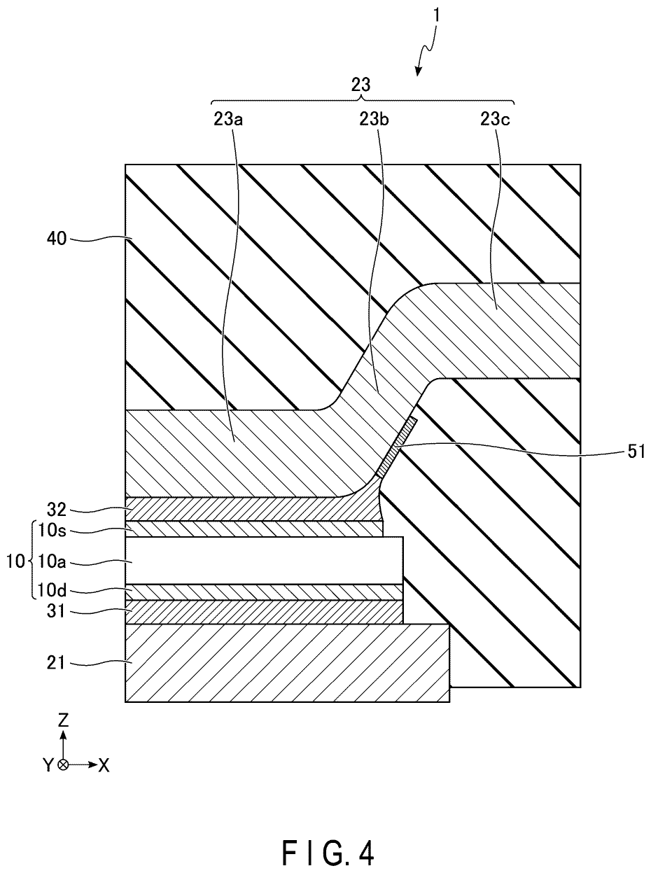

Next, a connection structure between the semiconductor chip 10 and the conductor 23 will be described with reference to FIG. 4. FIG. 4 is an enlarged view of a portion A in FIG. 3, and is a cross-sectional view illustrating the connection structure between the source electrode 10s of the semiconductor chip 10 and the conductor 23.

As described above, the source electrode 10s of the semiconductor chip 10 is connected to the portion 23a of the conductor 23 via the joint component 32. The conductor 23 includes the portion 23a extending linearly in the X direction, the portion 23b extending linearly from the portion 23a obliquely with respect to the X direction and the Z direction, and the portion 23c extending linearly from the portion 23b in the X direction.

The joint component 32 is provided between the source electrode 10s of the semiconductor chip 10 and the portion 23a of the conductor 23. The thin film 51 is provided on the lower surface of the portion 23b of the conductor 23, that is, on a surface in the X direction (or in the −Z direction) of the portion 23b. In other words, the thin film 51 is provided on the lower surface of the portion 23b of the conductor 23 on the joint component 32, that is, a surface continuous from a surface on which the joint component 32 is provided. The thin film 51 is in contact with the joint component 32.

The thin film 51 is arranged on a linearly extending surface (or region) of the portion 23b of the conductor 23. The thin film 51 is arranged from a beginning of the linearly extending surface of the portion 23b to the middle of the linearly extending surface. For example, the thin film 51 is arranged from the beginning of the linearly extending surface of the portion 23b to a length of about 200 μm. The length of 200 μm is a restriction in a case where a film is formed by plating, and may be set to a length of 200 μm or shorter or longer in a case where a film can be formed to the length of 200 μm or shorter or longer by plating or other manufacturing methods.

The thin film 51 may also be arranged from the beginning of the linearly extending surface of the portion 23b to the middle of the portion 23c, or to the end of the portion 23c, or to the middle of the portion 23d. The thin film 51 is preferably arranged from the beginning of the linearly extending surface of the portion 23b to the middle of the linearly extending surface. Alternatively, it is preferable that the thin film 51 is arranged from the beginning to the end of the linearly extending surface of the portion 23b. In other words, this is preferable to be arranged from the beginning of the linearly extending surface of the portion 23b to the end of the portion 23b.

Since adhesion between resin forming the resin component 40 and the thin film 51 is inferior to adhesion between copper forming the conductor 23 and the resin, the region where the thin film 51 is arranged is preferably small. By arranging the thin film 51 from the beginning of the linearly extending surface of the portion 23b to the middle of the linearly extending surface or to the end of the linearly extending surface, a contact area between the thin film 51 and the resin can be reduced, and deterioration in adhesion between the conductor 23 and the resin can be suppressed.

As illustrated in FIG. 2, a length in the Y direction of the thin film 51 is set to be equal to or shorter than a length in the Y direction of the portion 23b of the conductor 23.

As described above, the conductor 23 contains, for example, copper.

The thin film 51 mainly contains a material different from the joint component 32 and the conductor 23. The thin film 51 contains metal in which wettability of the joint component 32 is inferior to that of copper, in other words, contains metal in which the joint component 32 is less likely to wet and spread than copper. The thin film 51 mainly contains, for example, nickel (Ni) or aluminum (Al). The thin film 51 containing nickel or aluminum is formed by, for example, plating.

The thin film 51 may also include a metal oxide film, for example, copper oxide, nickel oxide, or aluminum oxide. A thickness of the metal oxide film is, for example, about 30 nm. The thin film 51 may also be an organic film, for example a solder resist.

Note that, in a case where the thin film 51 is copper oxide and the conductor 23 is copper, copper oxide is formed as a natural oxide film on a surface of the conductor 23 not in contact with the thin film 51 and other than this. The thin film 51 is distinguished from such natural oxide film. For example, a thickness of the natural oxide film is about 2 nm, and a thickness of the thin film 51 is about 30 nm. The thin film 51 is thicker than the natural oxide film. Furthermore, density of oxygen contained in the thin film 51 is higher than the density of oxygen contained in the natural oxide film.

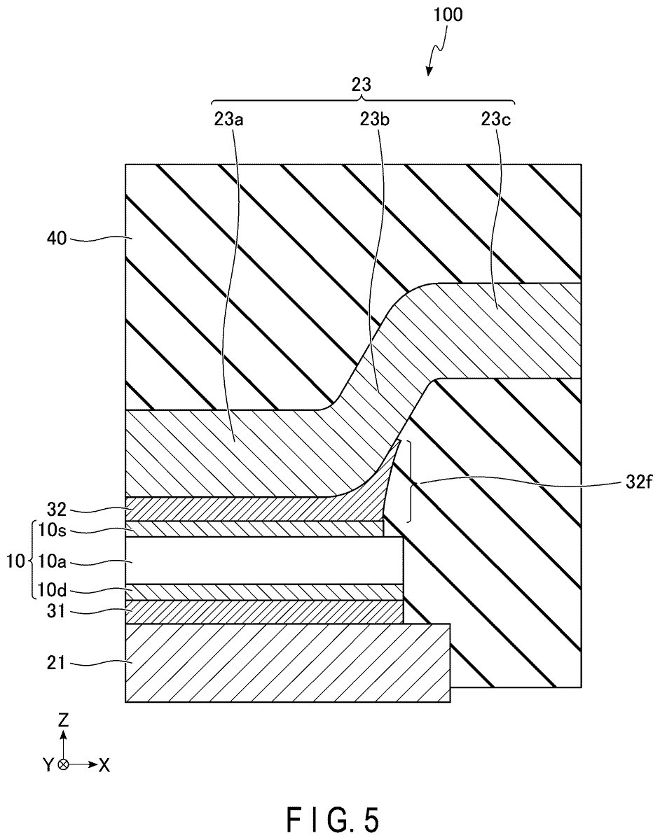

Hereinafter, a defect in a semiconductor device 100 according to a comparative example will be described with reference to FIG. 5, and an effect of the present embodiment will be described thereafter. FIG. 5 is an enlarged cross-sectional view illustrating a connection structure between a semiconductor chip 10 and a conductor 23 in the semiconductor device 100 according to the comparative example.

In the semiconductor device 100 according to the comparative example, a thin film is not provided on a lower surface of a portion 23b in the conductor 23. In such a structure, as illustrated in FIG. 5, a joint component 32 crawls up from an end of a region where the semiconductor chip 10 and a portion 23a are connected to each other to the portion 23b to form a large fillet 32f of the joint component 32 in some cases. When such fillet 32f is formed, a cavity in which the joint component 32 does not exist is formed between the semiconductor chip 10 and the conductor 23 due to an insufficient amount of the joint component 32 in some cases. In this case, a connection area between the semiconductor chip 10 and the conductor 23 becomes insufficient, and a resistance value in a source electrode increases. Furthermore, a current supply amount to the semiconductor chip 10 decreases, and a defect that performance of the semiconductor chip 10 cannot be sufficiently exhibited occurs.

If there is the cavity between the semiconductor chip 10 and the conductor 23, when a resin member 40 is formed, a part of resin of the resin member enters the cavity in some cases. When the resin enters the cavity, there is a possibility that thermal stress to a distal end of the semiconductor chip 10 and the conductor 23 into which the resin has entered increases due to a change in temperature caused by an external environment or thermal stress such as heat generated in the semiconductor device. Due to this increase in thermal stress, there is a possibility that breakdown occurs at an interface between the semiconductor chip 10 and the joint component 32 and an interface between the conductor 23 and the joint component 32.

In the semiconductor device 1 according to the present embodiment, the thin film 51 is provided on the lower surface of the portion 23b of the conductor 23, that is, on the same surface as the surface on which the joint component (for example, solder) 32 is provided.

By providing the thin film 51 in the portion 23b of the conductor 23, a crawling up amount of the joint component 32 to the portion 23b can be limited, and a size of the fillet formed on the end of the portion 23a can be controlled. Since the thin film 51 is a film having wettability inferior to that of copper forming the conductor 23, it is possible to prevent the joint component 32 from crawling up to the portion 23b.

Therefore, it is possible to reduce formation of the cavity between the semiconductor chip 10 and the conductor 23. Therefore, the connection area between the semiconductor chip 10 and the conductor 23 can be sufficiently secured, and it is possible to prevent the resistance value from increasing. Furthermore, the current supply amount to the semiconductor chip 10 can be prevented from decreasing, and the performance of the semiconductor chip 10 can be sufficiently exhibited.

Furthermore, since the formation of the cavity can be reduced, it is possible to prevent the entry of the resin into the cavity, and it is possible to suppress the thermal stress applied to the distal end of the semiconductor chip 10 and the conductor 23.

In the present embodiment, the thin film 51 is provided on a surface from the beginning of the linearly extending region to the middle of the linearly extending region of the portion 23b of the conductor 23.

Furthermore, the thin film 51 is not provided on the surface of the portion 23c of the conductor 23. Therefore, the contact area between the resin forming the resin member 40 and the thin film 51 is reduced. Since the adhesion between the thin film 51 and the resin is inferior to the adhesion between copper forming the conductor 23 and the resin, the deterioration in adhesion between the conductor 23 and the resin can be suppressed by reducing the contact area between the thin film 51 and the resin. Therefore, occurrence of peeling between the conductor 23 and the resin can be reduced, and reliability of the semiconductor device can be improved.

Note that, if there is no problem in adhesion between the conductor 23 and the resin, the thin film 51 may be provided from the beginning of the linearly extending surface to the end of the linearly extending surface of the portion 23b of the conductor 23. Furthermore, the thin film 51 may be provided on the surface of the portion 23c of the conductor 23.

### 2. Second Embodiment

A semiconductor device according to a second embodiment will be next described. In the second embodiment, a thin film 51 is provided from a bent portion between a portion 23a and a portion 23b to a linearly extending region of the portion 23b of a conductor 23. In the second embodiment, a point different from that in the first embodiment is mainly described. Other configurations not described are similar to those of the first embodiment.

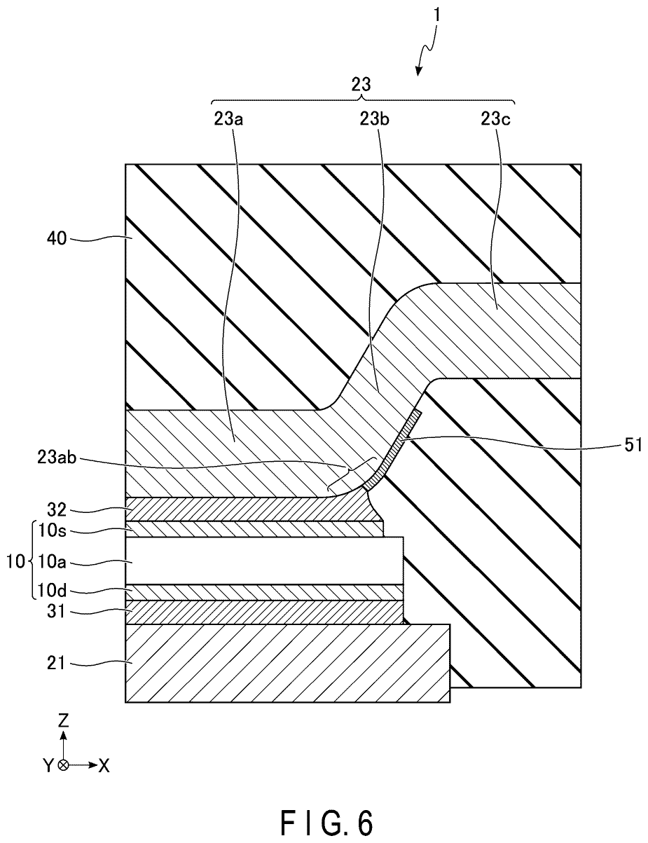

A connection structure between the semiconductor chip 10 and the conductor 23 in the second embodiment is described with reference to FIG. 6. FIG. 6 is an enlarged view of a portion A in FIG. 3, and is a cross-sectional view illustrating the connection structure between a source electrode 10s of the semiconductor chip 10 and the conductor 23.

The joint component 32 is provided between the source electrode 10s of the semiconductor chip 10 and the portion 23a of the conductor 23. The thin film 51 is provided on the lower surface of the portion 23b of the conductor 23, that is, on a surface in the X direction (or in the −Z direction) of the portion 23b.

A bent portion (or a curved portion) 23ab is provided between the portion 23a and the portion 23b of the conductor 23 (or a boundary therebetween). The bent portion 23ab is a region (or a surface) provided in a curved shape between the portion 23a and the portion 23b.

The thin film 51 is arranged from the bent portion 23ab between the portion 23a and the portion 23b to the linearly extending surface (or region) of the portion 23b of the conductor 23. That is, the thin film 51 is arranged on a part of the bent portion 23ab between the portion 23a and the portion 23b and the linearly extending surface of the portion 23b. The thin film 51 is arranged from the bent portion 23ab to the middle of the linearly extending surface of the portion 23b. The thin film 51 may also be arranged from the bent portion 23ab to the end of the linearly extending surface of the portion 23b, that is, to a position reaching the portion 23c.

In the second embodiment, the thin film 51 is provided in a part of the bent portion 23ab between the portion 23a and the portion 23b and the linearly extending surface of the portion 23b. Therefore, a crawling up amount of the joint component (for example, solder) 32 to the portion 23b can be limited, and a size of a fillet formed on an end of the portion 23a can be controlled more than in the first embodiment. Other effects of the second embodiment are similar to those of the first embodiment.

### 3. Third Embodiment

A semiconductor device according to a third embodiment will be next described. In the third embodiment, a thin film 51 is provided only in a bent portion 23ab between a portion 23b and a portion 23c of a conductor 23. In the third embodiment, a point different from that in the first embodiment is mainly described. Other configurations not described are similar to those of the first embodiment.

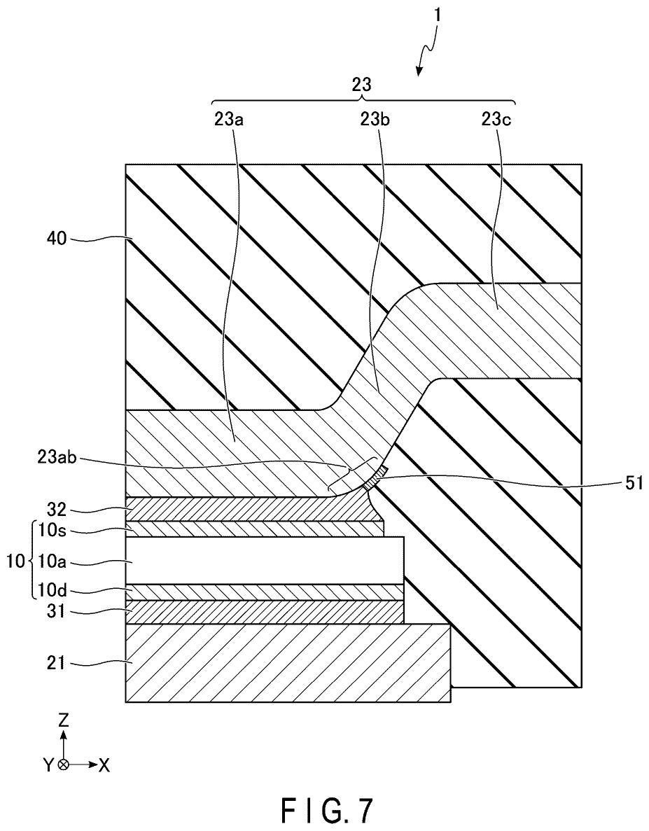

A connection structure between the semiconductor chip 10 and the conductor 23 in the third embodiment is described with reference to FIG. 7. FIG. 7 is an enlarged view of a portion A in FIG. 3, and is a cross-sectional view illustrating the connection structure between a source electrode 10s of the semiconductor chip 10 and the conductor 23.

The thin film 51 is arranged only on a surface of the bent portion 23ab between the portion 23a and the portion 23b of the conductor 23 and is not arranged on a linearly extending surface of the portion 23b.

In the third embodiment, a range in which the thin film 51 is arranged is narrower than that in the first and second embodiments, but even with such configuration, a crawling up amount of a joint component (for example, solder) 32 can be limited, and a size of a fillet formed on an end of the portion 23a can be controlled.

In the third embodiment, as compared with the first and second embodiments, a contact area between resin forming a resin member 40 and the thin film 51 can be reduced. This can further suppress a decrease in adhesion between the conductor 23 and the resin. Other effects of the third embodiment are similar to those of the first embodiment.

Note that, in the first to third embodiments described above, the example in which the semiconductor device forms the MOS field effect transistor (that is, MOSFET) has been described, but the semiconductor device may form another switching element, for example, an insulated gate bipolar transistor (IGBT). In a case where the semiconductor device forms the IGBT, a source corresponds to an emitter, and a drain corresponds to a collector.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first conductor;
a second conductor;
a semiconductor chip provided between the first conductor and the second conductor;
a first joint component provided between the semiconductor chip and the second conductor; and
a thin film provided on the second conductor, the film containing a material different from a material of the first joint component,
wherein the second conductor includes a first plate, a second plate, and a third plate,
the first plate extends in a first direction along a first surface of the semiconductor chip and is connected to the semiconductor chip via the first joint component,
the second plate extends from the first plate obliquely with respect to the first direction,
the third plate extends from the second plate in the first direction, and
the thin film is arranged on a surface of the second plate continuous from a surface on which the first joint component is provided.

2. The semiconductor device according to claim 1,
wherein the thin film is in contact with the first joint component.

3. The semiconductor device according to claim 1,
wherein the second conductor includes a bent portion between the first plate and the second plate, and the thin film is arranged on a surface of the bent portion.

4. The semiconductor device according to claim 3,
wherein the bent portion is a region provided in a curved shape between the first plate and the second plate.

5. The semiconductor device according to claim 1,
wherein the second plate of the second conductor includes a linearly extending surface, and
the thin film is arranged on the linearly extending surface.

6. The semiconductor device according to claim 5,
wherein the thin film is arranged from a beginning to a middle of the linearly extending surface.

7. The semiconductor device according to claim 5,
wherein the thin film is arranged from a beginning to an end of the linearly extending surface.

8. The semiconductor device according to claim 1, further comprising:
a third conductor provided separately from the first conductor; and
a second joint component,
wherein the second conductor includes a fourth plate,
the fourth plate extends from the third plate in a second direction intersecting the first direction, and further extends in the first direction, and
the second joint component is provided between the third conductor and the fourth plate.

9. The semiconductor device according to claim 1,
wherein the thin film contains a material different from a material of the second conductor.

10. The semiconductor device according to claim 1,
wherein the thin film contains one of nickel or aluminum.

11. The semiconductor device according to claim 1,
wherein the thin film includes a metal oxide film.

12. The semiconductor device according to claim 11,
wherein the metal oxide film contains one of copper oxide, nickel oxide, or aluminum oxide.

13. The semiconductor device according to claim 1,
wherein the thin film includes an organic film.

14. The semiconductor device according to claim 1,
wherein the first joint component contains solder.

15. The semiconductor device according to claim 1,
wherein the second conductor contains copper.

16. The semiconductor device according to claim 1,
wherein the semiconductor chip includes a MOS field effect transistor.

17. The semiconductor device according to claim 1,
wherein the semiconductor chip includes an insulated gate bipolar transistor (IGBT).
